(19) United States
(12) Patent Application Publication
(10) Pub. No.: US 2026/0372141 A1
(43) Pub. Date: Nov. 19, 2026

(54) THREE-DIMENSIONAL INTEGRATED PACKAGING STRUCTURE AND PACKAGING METHOD THEREFOR

(71) Applicant: HEFEI SMAT TECHNOLOGY CO. LTD., HEFEI CITY (CN)

(72) Inventor: Xiaochun TAN, HEFEI CITY (CN)

(21) Appl. No.: 19/676,155

(22) Filed: May 13, 2026

(30) Foreign Application Priority Data
May 14, 2025 (CN) 202510621803.7

(51) Int. Cl. H10W 70/652; H10D 1/20; H10D 80/20; H10D 80/30; H10W 44/20; H10W 70/09

(52) U.S. Cl. CPC H10W 70/652; H10D 1/20; H10D 80/211; H10D 80/30; H10W 44/209; H10W 70/09

(57) ABSTRACT

A three-dimensional integrated packaging structure and a packaging method therefor are provided. The packaging structure comprises: a flip-chip or face-up chip; an inductor vertically stacked and electrically connected with the die through a redistribution layer which is electrically led out to an exterior of the packaging structure; a stacking direction of the inductor and the die is parallel to a thickness direction of the die, and elements are physically isolated through an insulating dielectric layer. The inductor comprises a magnetic core and has a spiral structure, multi-turn overlapping structure, or segmented winding structure. A spiral coil surrounds the magnetic core and comprises trace A, trace B, and trace C. The magnetic core and the spiral coil are encapsulated by the insulating dielectric layer. The three-dimensional structure saves space, reduces parasitic inductance and resistance, provides stable signal transmission and low EMI, and is applicable to miniaturized, highly integrated chip packaging.

### CROSS-REFERENCE TO RELATED APPLICATIONS

The present disclosure claims priority to a Chinese patent application No. 202510621803.7, filed on May 14, 2025, and entitled " Three-Dimensional Integrated Packaging Structure and Packaging Method Therefor", the entire contents of which are incorporated herein by reference, including the specification, claims, drawings and abstract.

### FIELD OF TECHNOLOGY

The present disclosure relates to a field of die packaging, particularly, to a three-dimensional integrated packaging structure and a packaging method therefor.

### BACKGROUND

With continuous advancement of integrated circuit packaging technology, integration density is increasing, functionality is becoming richer, and overall packaging dimensions are continuously developing toward miniaturization and even microminiaturization. In some structures, it is necessary to electrically connect dies with other devices, such as in semiconductor or other die device packaging fields, where certain specific types of dies need to be integrated or stacked and packaged with inductors, mainly for achieving efficient energy conversion, signal processing, or radio frequency (RF) functions.

Current packaging fields generally adopt planar spatial layout solutions, that is, inductors or other components and dies (such as power devices, RF dies, etc.) are usually arranged side by side or embedded in substrate designs. These design solutions have some technical defects: low space utilization, layout resulting in redundant packaging area, difficulty in meeting the requirements for high-density integration in miniaturization scenarios such as mobile terminals; limited high-frequency performance, long electrical connection paths, large parasitic resistance, causing serious signal loss and electromagnetic interference.

### SUMMARY OF THE DISCLOSURE

To solve the above problems in the prior art, the present disclosure provides a three-dimensional integrated packaging structure and a packaging method therefor.

To achieve the above object, a three-dimensional integrated packaging structure is proposed by the present disclosure and comprises:
a die mounted in a flip-chip manner or a face-up manner, having an active surface and a back surface opposite to the active surface;
an inductor vertically stacked and electrically connected with the die through a redistribution layer;
an external connection structure for electrically leading out the die to an exterior of a packaging structure;
wherein a stacking direction of the inductor and the die is parallel to a thickness direction of the die, and the inductor, the die, the redistribution layer, and the external connection structure are physically isolated through an insulating dielectric layer.

Further, the inductor has a spiral structure, multi-turn overlapping structure, or segmented winding structure.

Further, the inductor is formed by a layer-by-layer encapsulation and electroplating process, and an inductance value of the inductor ranges from 1 nH to 100 μH.

Further, the inductor comprises a magnetic core, and a spiral coil surrounding a surface of the magnetic core is formed through etching and electroplating processes, the spiral coil comprises a trace A, a trace B, and a trace C, and the magnetic core and the spiral coil are encapsulated by the insulating dielectric layer.

Further, in a case where the die is mounted in the face-up manner, the inductor is stacked below the back surface of the die; and in a case where the die is mounted in the flip-chip manner, the inductor is stacked below the active surface of the die.

Further, in a case where the die is mounted in the face-up manner, the back surface of the die is exposed to an exterior of the insulating dielectric layer.

Further, the external connection structure is metal pillar formed by etching the insulating dielectric layer to form a groove and electroplating metal to fill the groove.

Further, a material of the insulating dielectric layer is a molding compound.

Further, the packaging structure is further integrated into a fan-out wafer-level package module or a system-in-package module.

A packaging method for a three-dimensional integrated structure, comprising steps of:
encapsulating an inductor: forming the inductor through a layer-by-layer encapsulation and electroplating process;
electroplating a redistribution layer: electrically redistributing the inductor after electroplating the redistribution layer;
mounting a die: mounting the die in a face-up manner or a flip-chip manner, vertically stacking and electrically connecting the die with the inductor through the redistribution layer;
electroplating an external connection structure: electrically leading out the die to an exterior of a packaging structure;
wherein a stacking direction of the inductor and the die is parallel to a thickness direction of the die, and the inductor, the die, the redistribution layer, and the external connection structure are physically isolated through an insulating dielectric layer.

Further, in the step of encapsulating the inductor, the inductor has a spiral structure, multi-turn overlapping structure, or segmented winding structure.

Further, in the step of encapsulating the inductor, an inductance value of the inductor ranges from 1 nH to 100 μH.

Further, in the step of encapsulating the inductor, traces A are electroplated on the insulating dielectric layer, the insulating dielectric layer is used to encapsulate the traces A and is ground to expose top surfaces of the traces A, a magnetic core is mounted on the top surfaces of the traces A, the magnetic core is further encapsulated and a top surface of the magnetic core is exposed, the insulating dielectric layer is etched to expose ends of the traces A, traces B are electroplated in etched grooves respectively to connect with the traces A, traces C are electroplated on an exposed top surface of the magnetic core to connect with the traces B, the traces A, the traces B, and the traces C form a spiral coil surrounding the magnetic core, and encapsulation is performed again so that the magnetic core and the spiral coil are encapsulated by the insulating dielectric layer.

Further, in the step of mounting the die, in a case where the die is mounted in the face-up manner, the inductor is stacked below the back surface of the die; and in a case where the die is mounted in the flip-chip manner, the inductor is stacked below the active surface of the die.

Further, in the step of mounting the die, in a case where the die is mounted in the face-up manner, the back surface of the die is exposed to an exterior of the insulating dielectric layer.

Further, in the step of electroplating the external connection structure, the external connection structure is metal pillar formed by etching the insulating dielectric layer to form a groove and electroplating metal to fill the groove.

Further, a material of the insulating dielectric layer of the steps is a molding compound.

Further, the packaging method further comprises integrating the packaging structure into a fan-out wafer-level package module or a system-in-package module.

The three-dimensional integrated packaging structure and packaging method therefor provided by the present disclosure have following advantages:
1. In a stacked structure, the inductor is formed by layer-by-layer encapsulation and electroplating, reasonably utilizing packaging space to adjust coil turns, increasing inductance, reducing inductor volume, and reducing inter-layer capacitance, being applicable to die packaging fields requiring miniaturization and high integration, and reasonably arranging electrical ports through redistribution and reasonably configuring packaging space, resulting in a compact product structure.
2. The inductor and the die are stacked in a flip-chip manner or a face-up manner, the three-dimensional structure saves space, the product has a wide application range and high design flexibility, parasitic inductance and resistance are reduced, signal transmission is stable, electromagnetic interference is low, and a close layout of the inductor and the die can reduce loop impedance.

### BRIEF DESCRIPTION OF THE DRAWINGS

FIGS. 1-7 are cross-sectional views of steps of electroplating an inductor of a packaging method for a three-dimensional integrated structure according to the present disclosure;

FIGS. 8-11 are cross-sectional views of steps of electroplating a redistribution layer of Embodiment 1 of a packaging method for a three-dimensional integrated structure according to the present disclosure;

FIGS. 12-14 are cross-sectional views of steps of mounting a die of Embodiment 1 of a packaging method for a three-dimensional integrated structure according to the present disclosure;

FIGS. 15-17 are cross-sectional views of steps of electroplating an external connection structure of Embodiment 1 of a packaging method for a three-dimensional integrated structure according to the present disclosure;

FIG. 18 is a cross-sectional view of a product of Embodiment 1 of a three-dimensional integrated packaging structure according to the present disclosure;

FIGS. 19-21 are cross-sectional views of steps of electroplating a redistribution layer of Embodiment 2 of a packaging method for a three-dimensional integrated structure according to the present disclosure;

FIGS. 22-24 are cross-sectional views of steps of mounting a die of Embodiment 2 of a packaging method for a three-dimensional integrated structure according to the present disclosure;

FIGS. 25-29 are cross-sectional views of steps of electroplating an external connection structure of Embodiment 2 of a packaging method for a three-dimensional integrated structure according to the present disclosure;

FIG. 30 is a cross-sectional view of a product of Embodiment 2 of a three-dimensional integrated packaging structure according to the present disclosure.

In the drawings: 1. die; 2. inductor; 3. redistribution layer; 4. metal pillar; 5. insulating dielectric layer; 6. trace A; 7. trace C; 8. magnetic core.

### DETAILED DESCRIPTION OF THE DISCLOSURE

To make the objectives, technical solutions, and advantages of the present disclosure clearer, the technical solutions of the present disclosure will be described clearly and completely below in conjunction with the drawings of the present disclosure. Apparently, the described embodiments are part of the embodiments of the present disclosure, rather than all embodiments. Based on the embodiments of the present disclosure, all other embodiments obtained by those of ordinary skill in the art without creative effort shall fall within the protection scope of the present disclosure; the content of the present disclosure will be illustrated below in conjunction with specific implementation manners, and examples of the implementation manners are shown in the drawings, wherein the same or similar reference numerals represent the same or similar components or components having the same or similar functions throughout.

The terms "first", "second", and the like in the specification and claims of the present disclosure and the above-mentioned accompanying drawings are used to distinguish similar objects and are not necessarily used to describe a specific sequence or order. It should be understood that such data may be interchanged in appropriate circumstances so that the embodiments described herein can be implemented in sequences other than those illustrated or described herein; the directional terms mentioned in the present disclosure, such as top, bottom, left, right, front, back, interior, exterior, front side, back side, side, and the like, merely refer to directions in the drawings, and the implementation manners described below with reference to the drawings and the directional terms used are exemplary and are only used to explain the present disclosure and should not be construed as limiting the present disclosure. In addition, various specific examples of processes and materials provided in the present disclosure are examples that those of ordinary skill in the art may recognize for application of other processes and/or use of other materials.

To better understand the objectives, structure, and functions of the present disclosure, a three-dimensional integrated packaging structure and a packaging method therefor proposed by the present disclosure will be further described in detail below in conjunction with the drawings. The packaging method comprises steps of:
Encapsulating an inductor 2: forming the inductor 2 through layer-by-layer encapsulation and electroplating processes;
Electroplating a redistribution layer 3: electrically redistributing the inductor 2 after electroplating the redistribution layer 3;
Mounting a die 1: mounting the die 1 in a face-up manner or a flip-chip manner, vertically stacking and electrically connecting the die 1 with the inductor 2 through the redistribution layer 3;
Electroplating an external connection structure: electrically leading out the redistribution layer 3 to an exterior of the packaging structure;
Wherein a stacking direction of the inductor 2 and the die 1 is parallel to a thickness direction of the die 1, and the inductor 2, the die 1, the redistribution layer 3, and the external connection structure are physically isolated through an insulating dielectric layer 5.

The above steps are not limited to any particular sequence. The inductor 2 may be electroplated and encapsulated first, and then the die 1 may be mounted and subsequent processing continued. Alternatively, the die 1 may be mounted and encapsulated first, and then the inductor 2 may be electroplated and encapsulated and subsequent processing continued. The present disclosure takes the first sequential step as an example.

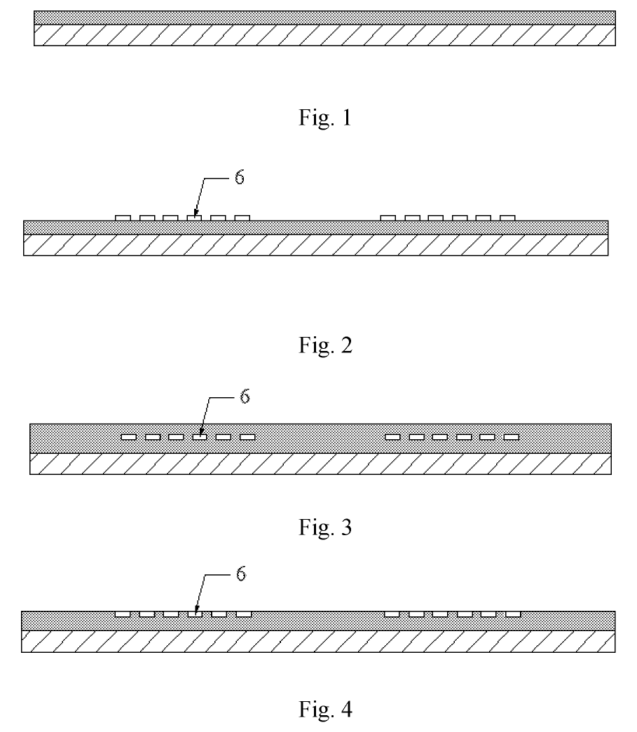

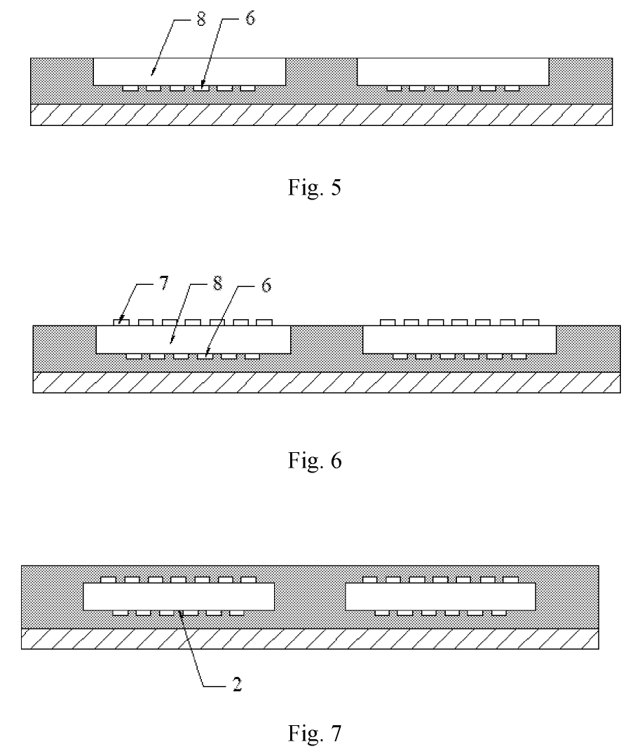

A more specific process flow of the inductor encapsulation process steps comprises:
S1: providing a substrate, which may be a resin board commonly used in the art, covering the substrate with the insulating dielectric layer 5 of a certain thickness (as shown in FIG. 1), a surface of the insulating dielectric layer 5 being horizontally flat after curing, and traces being electroplated after covering with the insulating dielectric layer 5 to prevent the risk of bottom the trace detachment and failure when the substrate is stripped and removed in subsequent processes.
S2: electroplating the traces A6 on an upper surface of the insulating dielectric layer 5 (as shown in FIG. 2), the traces A6 comprising a plurality of parallel arranged and uniformly spaced electroplated metals, with no limitation on the height, width, or spacing of the electroplated the traces A6.
S3: using the insulating dielectric layer 5 to continue completely encapsulating the traces A6 on the basis of the insulating dielectric layer 5 of S1 to form a new encapsulation top surface (as shown in FIG. 3), the two portions of the insulating dielectric layer 5 combining into a complete portion.
S4: horizontally grinding the encapsulation top surface formed in step S3 by mechanical grinding until the top surface of the traces A6 is exposed, the ground encapsulation top surface being horizontally flat (as shown in FIG. 4).
S5: mounting a magnetic core 8 at positions corresponding to the traces A6 on the ground encapsulation top surface, the magnetic core 8 being in direct contact with the traces A6, and continuing to completely encapsulate the magnetic core 8 with the insulating dielectric layer 5 to form an encapsulation top surface again, and exposing the top surface of the magnetic core 8 by mechanically grinding the encapsulation top surface (as shown in FIG. 5), the layer-by-layer encapsulation causing the insulating dielectric layer 5 to constitute an integral whole.
S6: etching corresponding positions of the insulating dielectric layer 5 to form a plurality of grooves, two end portions of the traces A6 being exposed in corresponding grooves, and filling the grooves with the traces B (not shown in the figure) of electroplated metal through an electroplating process, the traces B being connected with the traces A6.
S7: electroplating the traces C7 on the exposed top surface of the magnetic core 8, the traces C7 connecting the traces A6 and the traces B together, the traces A6, the traces B, and the traces C7 constituting a spiral coil surrounding the magnetic core 8, encapsulating again so that the magnetic core 8 and the spiral coil are encapsulated by the insulating dielectric layer 5, the encapsulation top surface being horizontally flat (as shown in FIG. 7), the whole constituting an inductor 2 packaging structure, the inductor 2 being formed through layer-by-layer encapsulation and electroplating processes, and depending on the substrate area size and actual product space occupation size, a plurality of inductor 2 structures may be formed on the substrate at one time, the present disclosure taking the formation of two inductors 2 at one time as an example.

The inductor 2 may have a spiral structure, a multi-turn overlapping structure, or a segmented winding structure; in the present disclosure, the inductor 2 is exemplified as a spiral type, and through layer-by-layer encapsulation, electroplating, and other processes, a spiral coil of the traces A6, the traces B, and the traces C7 surrounding the magnetic core 8 is formed, thereby forming an inductor 2 structure encapsulated in the insulating dielectric layer 5, which can increase the number of coil turns in a limited space, significantly increase the inductance, reduce the volume of the inductor 2, miniaturize the device, and is suitable for high-integration die 1 packaging; the layer-by-layer encapsulated dielectric material can effectively reduce inter-layer capacitance, increase the self-resonant frequency of the inductor 2, and extend the high-frequency operating range; fine control of coil patterns is possible, and winding limitations of special-shaped magnetic cores 8 can be overcome, with high flexibility in electroplating fabrication.

In practical applications, the selection of the inductor 2 needs to be determined according to specific circuit requirements; for example, in power supply filter circuits, the selection of inductance value affects filtering effects and circuit stability; in LC oscillation circuits, the selection of inductance value affects oscillation frequency; the inductance value range of the inductor 2 in the present disclosure is from 1 nH to 100 μH, and this inductance value range is applicable to different circuits and application scenarios, with power management dies 1, radio frequency dies 1, analog or mixed-signal dies 1, etc., matching different ranges of inductance values.

### Embodiment 1

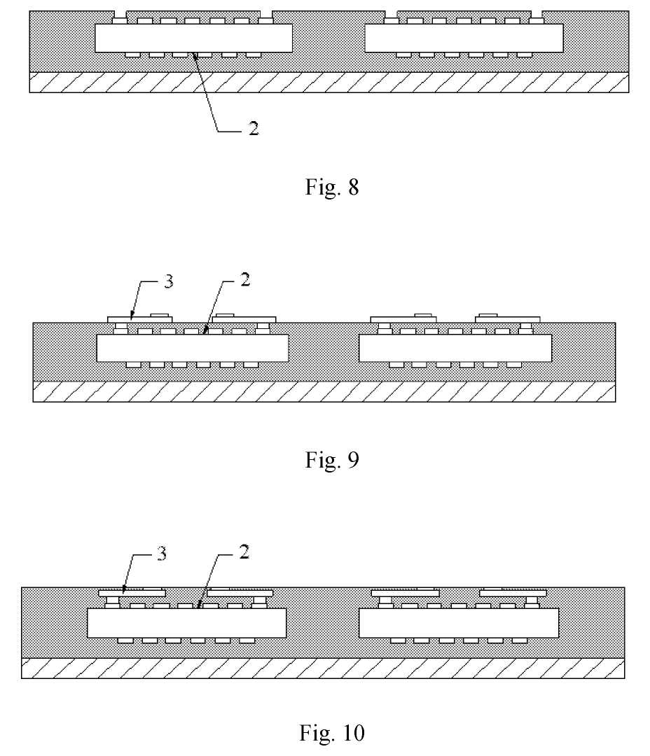

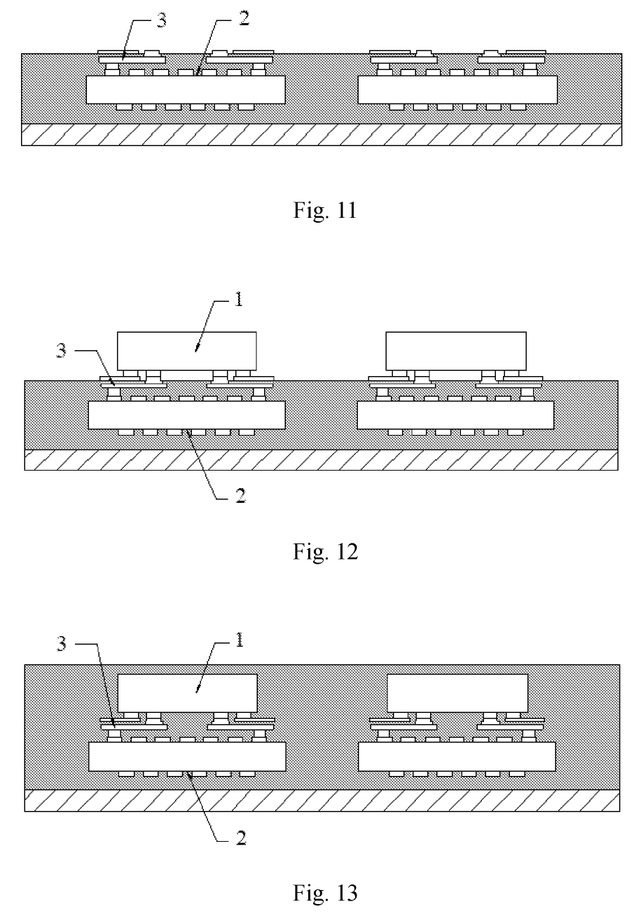

The more specific process flow of the step of electroplating the redistribution layer 3 is as follows:
S1: etching corresponding positions on the insulating dielectric layer 5 encapsulating the top surface of the traces C7 through an etching process, so that an end portion of the traces C7 is exposed at the bottom of an etched groove (as shown in FIG. 8), the exposed end portion of the traces C7 being a separate end portion with no other connection relationship, serving as an external port for connecting the inductor 2 with other components.
S2: electroplating metal to fill the etched groove through an electroplating process within the etched groove, and extending electroplated metal on the surface of the insulating dielectric layer 5 to constitute the redistribution layer 3 (as shown in FIG. 9), the redistribution layer 3 rearranging the position of the external port of the inductor 2 and flexibly readjusting according to the connection relationship between the inductor 2 and other connected components, the extension direction of the redistribution layer 3 being designed according to actual product conditions, for example, when the inductor 2 is large in size and other components electrically connected to the inductor 2 such as die 1 are small in size, making it difficult to match and connect electrical ports between the two, at this time the electrical port positions are adjusted by electroplating the redistribution layer 3 to achieve connection between the two, and simultaneously electroplating conductive bumps (not shown in the figure) on the redistribution layer 3 as electrical ports for external connection of the redistribution layer 3.
S3: continuing to use the insulating dielectric layer 5 to completely encapsulate the redistribution layer 3 and the conductive bumps, and horizontally mechanically grinding the encapsulation top surface until the top surfaces of the conductive bumps are exposed (as shown in FIG. 10), the exposed top surfaces of the conductive bumps serving as ports for external electrical connection; further, in order to lead out the electricity of die 1 to the exterior of the packaging structure, continuing to electroplate other lead layers on the insulating dielectric layer 5 ground to expose the top surfaces of the conductive bumps (as shown in FIG. 11, wherein the lead layers are not shown in the figure), and simultaneously electroplating the top surfaces of the conductive bumps to the same height as the lead layers.

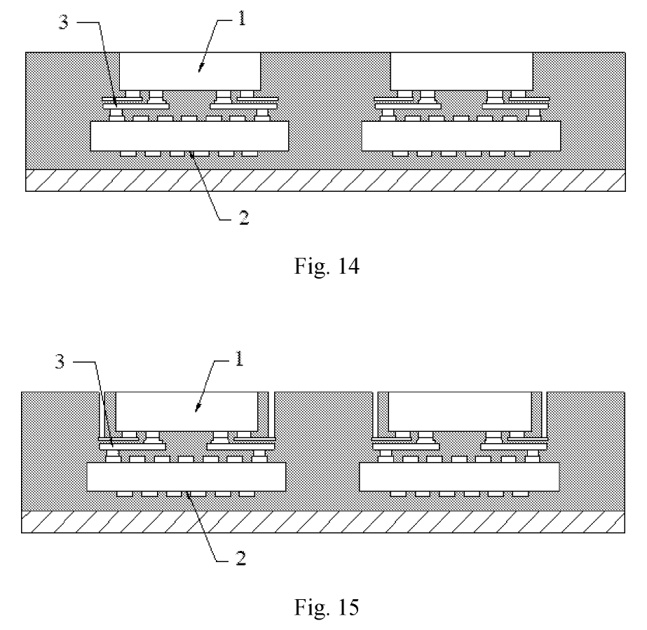

The more specific process flow of the die 1 mounting step is as follows:
S1: mounting die 1 in a flip-chip manner, the die 1 may be a power management die 1, a radio frequency die 1, an analog or mixed-signal die 1, etc., the die 1 having an active surface and a back surface opposite to the active surface, the active surface of the die 1 having electrical ports of the die 1 such as bumps (conductive bumps), mounting the die 1 with the active surface facing the conductive bumps, the conductive bumps of the electrical ports of the die 1 being soldered to the conductive bumps of the redistribution layer 3 through solder paste, and other conductive bumps of the electrical ports of the die 1 being soldered to the lead layers through solder paste, thereby achieving flip-chip mounting of the die 1 (as shown in FIG. 12), thus the die 1 achieving electrical connection with the inductor 2 through the redistribution layer 3; in a power management die 1 packaging structure, the inductor 2 serves as an energy storage element for smoothing current, filtering high-frequency noise, and participating in energy conversion (such as inductor-capacitor (LC) filtering in switching power supplies); in a radio frequency die 1 packaging structure, the inductor 2 is used for impedance matching, resonant circuits (such as LC oscillators), filtering (such as band-pass filters), or radio frequency signal coupling; in an analog or mixed-signal die 1 packaging structure, the inductor 2 is used for eliminating power supply noise, suppressing electromagnetic interference (EMI), or constructing low-pass/high-pass filters.
S2: similarly using the insulating dielectric layer 5 to completely encapsulate the die 1 (as shown in FIG. 13), further, in order to improve the heat dissipation performance of the packaging structure, the back surface of the die 1 may be exposed by horizontally mechanically grinding the top surface of the cured insulating dielectric layer 5 after encapsulation is completed (as shown in FIG. 14), the back surface of the die 1 being exposed outside the insulating dielectric layer 5 to directly dissipate heat to the exterior of the insulating dielectric layer 5, avoiding heat accumulation inside the packaging structure due to the thermal resistance of the insulating dielectric layer 5 causing thermal damage to internal structures, and simultaneously covering the exposed back surface of the die 1 with a protective layer commonly used in the art to extend device service life.

After die 1 mounting, the stacking direction of the inductor 2 and the die 1 is parallel to the thickness direction of the die 1, and the insulating dielectric layer 5 provides physical isolation between the inductor 2, the die 1, the redistribution layer 3, and the external connection structure.

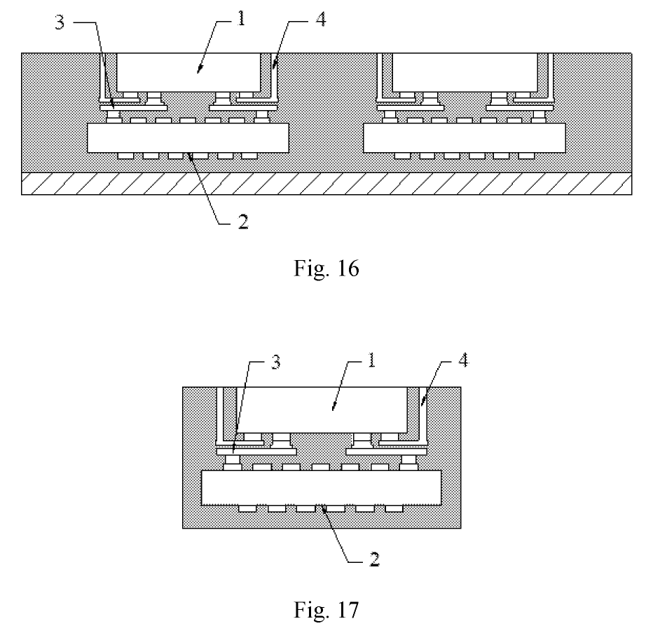

The more specific process flow of the step of electroplating the external connection structure is as follows:
S1: etching the insulating dielectric layer 5 at corresponding positions on the ground top surface of the insulating dielectric layer 5 through an etching process so that one end of the lead layer is exposed in an etched groove (as shown in FIG. 15).
S2: electroplating metal to fill the etched grooves on the insulating dielectric layer 5 to form metal pillars 4, the bottom ends of the metal pillars 4 being connected integrally with the lead layers, and the top ends of the metal pillars 4 being exposed flush with the upper surface of the insulating dielectric layer 5 (as shown in FIG. 16), the electricity of die 1 being connected to the exterior of the packaging structure through the lead layers and the metal pillars 4.
S3: for cases where a plurality of inductors 2 are formed on the substrate at one time, after completion of the inductors 2, all subsequent process steps form the same structure on each inductor 2, and finally a cutting step is required, cutting the insulating dielectric layer 5 to separate each product unit (as shown in FIG. 17), and stripping the substrate to obtain a plurality of product units at one time; since the present disclosure forms two inductors 2 at one time, accordingly, two product units are finally formed at one time.

In this embodiment of the present disclosure, the inductor 2 is stacked below the active surface of the die 1, the stacking direction of the inductor 2 and the die 1 is parallel to the thickness direction of the die 1, the inductor 2 and the die 1 are stacked and packaged vertically, the electrical connection ports of the inductor 2 packaging structure are rearranged through the electroplated redistribution layer 3 to electrically connect with the conductive bumps on the active surface of the flip-chip mounted die 1, rationally utilizing packaging space with a compact structure and high integration density to meet miniaturized device requirements; the die 1 is flip-chip mounted, the active surface of the die 1 and the electrical interface of the inductor 2 (redistribution layer 3) being close to each other, the connection path between the die 1 and the inductor 2 being short, reducing parasitic inductance and resistance, suitable for high-frequency circuit requirements, reducing inductor loss, and improving power conversion; suitable for packaging structure designs such as high-frequency, high-power-density, and miniature types, such as radio frequency dies 1, power management dies 1, etc.

### Embodiment 2

Different from the flip-chip mounting and stacking of the inductor 2 and the die 1 in Embodiment 1, in this embodiment the inductor 2 and the die 1 are stacked by face-up mounting.

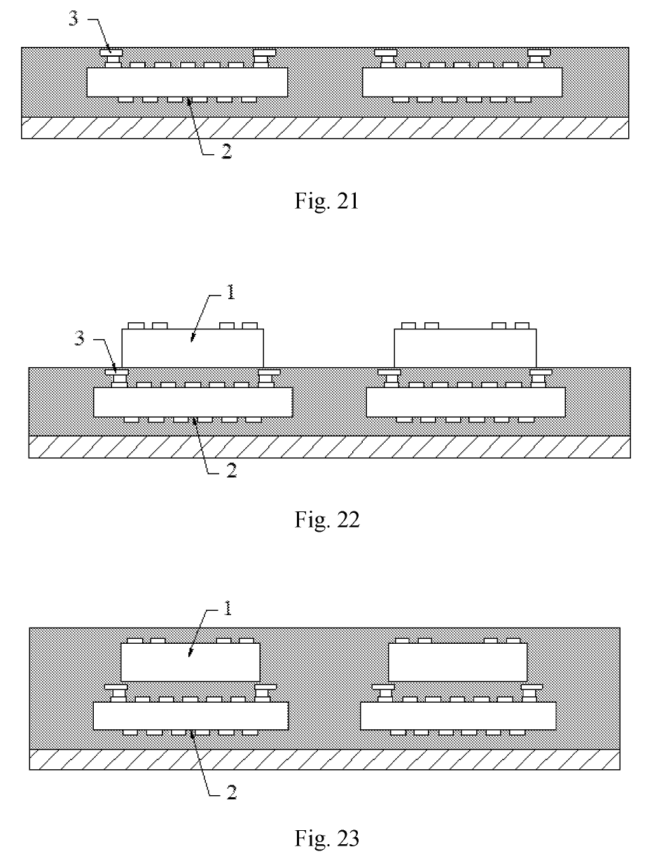

The more specific process flow of the step of electroplating the redistribution layer 3 is as follows:
S1: etching corresponding positions on the insulating dielectric layer 5 encapsulating the top surface of the traces C7 through an etching process, so that an end portion of the traces C7 is exposed at the bottom of an etched groove (as shown in FIG. 19), the exposed end portion of the traces C7 being a separate end portion with no other connection relationship, serving as an external port for connecting the inductor 2 with other components.
S2: Electroplating metal in the etched groove by an electroplating process to fill the groove, and electroplating metal extending on the surface of the insulating dielectric layer 5 to constitute a redistribution layer 3 (as shown in FIG. 20). The redistribution layer 3 re-lays out external port positions of the inductor 2, and flexibly readjusts according to a connection relationship between the inductor 2 and other connecting components. An extending direction of the redistribution layer 3 is designed according to actual product conditions. For example, when the inductor 2 has a large size while other components electrically connected to the inductor 2, such as the die 1, have a small size, and electrical ports between the two are difficult to match to achieve connection, the redistribution layer 3 is electroplated at this time to adjust electrical port positions to achieve connection between the two.
S3: Continuing to use the insulating dielectric layer 5 to completely encapsulate the redistribution layer 3 (as shown in FIG. 21).

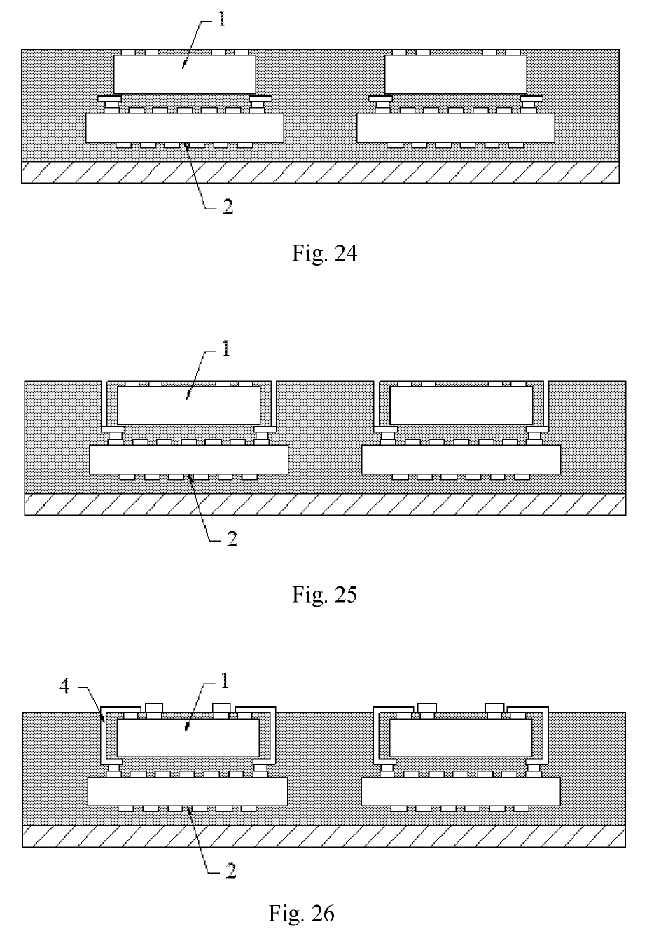

A more specific process for the die 1 mounting step is as follows:
S1: Mounting the die in a face-up manner, wherein the die 1 is the same as in Embodiment 1. The die 1 is mounted with a back surface thereof facing the insulating dielectric layer 5, and the die 1 is located above the inductor 2 (as shown in FIG. 22).
S2: Using the insulating dielectric layer 5 to completely encapsulate the die 1 (as shown in FIG. 23), and horizontally mechanically grinding an encapsulation top surface until conductive pads on an active surface of the die 1 are exposed. The ground encapsulation top surface is horizontally flat after grinding (as shown in FIG. 24).

After the die 1 is mounted, a stacking direction of the inductor 2 and the die 1 is parallel to the thickness direction of the die 1, and the two, the redistribution layer 3, and the extraction structure are physically isolated by the insulating dielectric layer 5.

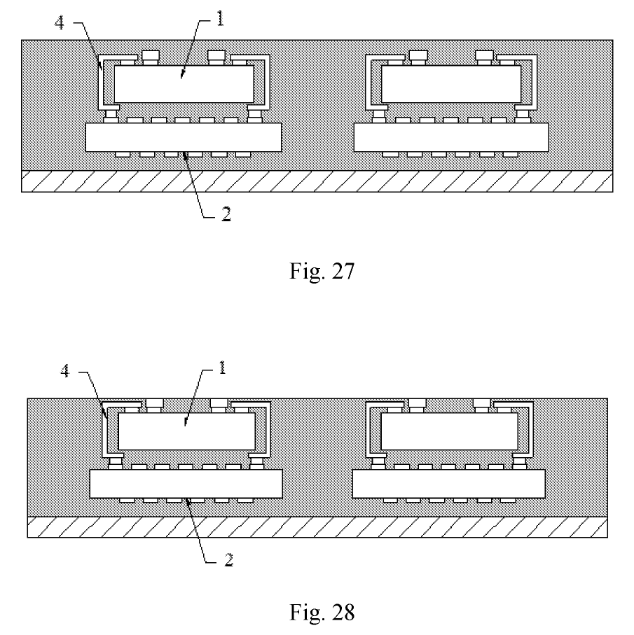

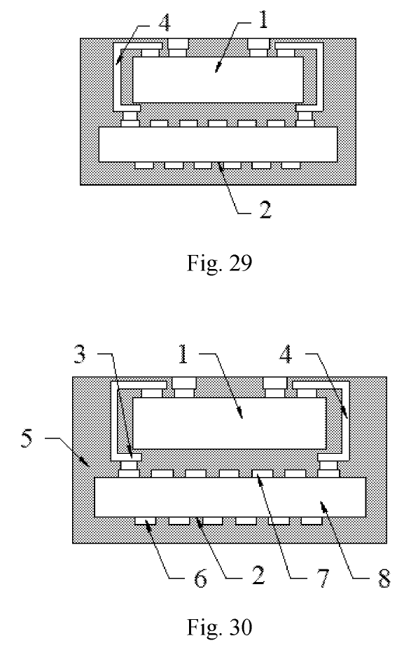

A more specific process for the electroplating extraction structure step is as follows:
S1: Vertically etching the insulating dielectric layer 5 at corresponding positions on the encapsulation top surface until an end portion of the redistribution layer 3 is exposed (as shown in FIG. 25).
S2: Electroplating a metal pillar 4 to fill the etched groove. A bottom end of the metal pillar 4 is electrically connected integrally with the end portion of the redistribution layer 3. The electroplated metal extends on a top surface of the insulating dielectric layer 5 to form a wiring layer. The wiring layer is electrically connected to partially exposed conductive pads on the active surface of the die 1. Other exposed conductive pads on the active surface of the die 1 are also electroplated with metal to increase height (as shown in FIG. 26).
S3: Using the insulating dielectric layer 5 to encapsulate the electroplated metal and electroplated height-increasing portions on the conductive pads (as shown in FIG. 27). Horizontally grinding the encapsulation top surface by mechanical grinding until the electroplated height-increasing portions on the conductive pads are exposed (as shown in FIG. 28). For cases where a plurality of inductors 2 are formed on a substrate at one time, after the inductors 2 are completed, all subsequent process steps form the same structure on each inductor 2. Finally, a cutting step is required to cut the insulating dielectric layer 5 to separate each product unit (as shown in FIG. 29).

In this embodiment, the inductor 2 is stacked below the back surface of the die 1. A stacking direction of the inductor 2 and the die 1 is parallel to the thickness direction of the die 1. The inductor 2 and the die 1 are vertically stacked and packaged. Electrical connection ports of the inductor 2 packaging structure are re-laid out by the electroplated redistribution layer 3 to be electrically connected with conductive pads on the active surface of the face-up mounted die 1, reasonably utilizing packaging space. The die 1 is face-up mounted, and the inductor 2 is stacked on the back surface of the die 1, which can reduce direct heat conduction from the inductor 2 to the die 1, and is suitable for low-power scenarios. The face-up mounting process for the die 1 has high maturity and low cost, and is suitable for packaging structure designs such as low-cost, high-power inductor 2 and die 1 stacking, such as analog or mixed-signal dies 1.

In the above Embodiment 1, Embodiment 2, and other embodiments, finally, according to specific conditions of actual products, external solder pads may be electroplated on top ends of the metal pillars 4 exposed on the surface of the insulating dielectric layer 5 or on the height-increasing portions on the conductive pads of the active surface of the die 1. The external solder pads may serve as a medium for external devices to be electrically connected to an internal structure of the insulating dielectric layer 5. The entire product unit may be further integrated into a fan-out wafer-level package or a system-in-package module through the external solder pads, or integrated into other suitable packaging modules. Of course, the embodiments and drawings of the present disclosure only show partial electrical connection relationships and electrical paths of the components, and other necessary electrical connection relationships and electrical paths of the components, such as electrical grounding, also fall within the protection scope of the present disclosure.

Moreover, in all encapsulation processes using the insulating dielectric layer 5 in the present disclosure, the encapsulation method is molding. Materials selected for molding may be epoxy resin, cyanate ester, polyimide, etc., having advantages such as low cost and good curing performance. The packaging method plays an important role in the field of semiconductor manufacturing, mainly reflected in aspects such as protection, connection, support, reliability, and promoting technological progress. The die 1 is protected from environmental humidity and other invasions and mechanical vibration and impact damage through packaging. The encapsulation method is other suitable methods commonly used in the art, such as compression molding injection.

All processes for grinding the encapsulation top surface after encapsulation in the present disclosure use grinding machines commonly used in the technical field to perform surface treatment on the encapsulation top surface, that is, horizontal mechanical grinding on the encapsulation top surface, so that a final ground surface is horizontally flat, and an outer surface of the entire packaging structure is flat and smooth.

The electroplating processes used in the present disclosure all first use a photoresist film to form electroplating protection mask on a surface through photolithography techniques of exposure and development, protecting places where electroplating is not needed with the photoresist film and exposing regions where electroplating is needed. Then, a metal seed layer is formed in the regions to be electroplated by suitable methods such as sputtering or copper deposition. The metal seed layer is copper or other metal material. The metal seed layer is to ensure adhesion between subsequently electroplated metals and between metal and encapsulation material, while providing a surface for conductive ions to attach for electroplating to ensure electroplating effects. The entire steps in the electroplating process and materials used are also technical common knowledge in the art. In all electroplating processes of the present disclosure, the electroplated metal is copper or other metal material.

Through the packaging methods of the three-dimensional integrated structure of the above Embodiment 1, Embodiment 2, and other embodiments, a three-dimensional integrated packaging structure can be obtained. The structure comprises:

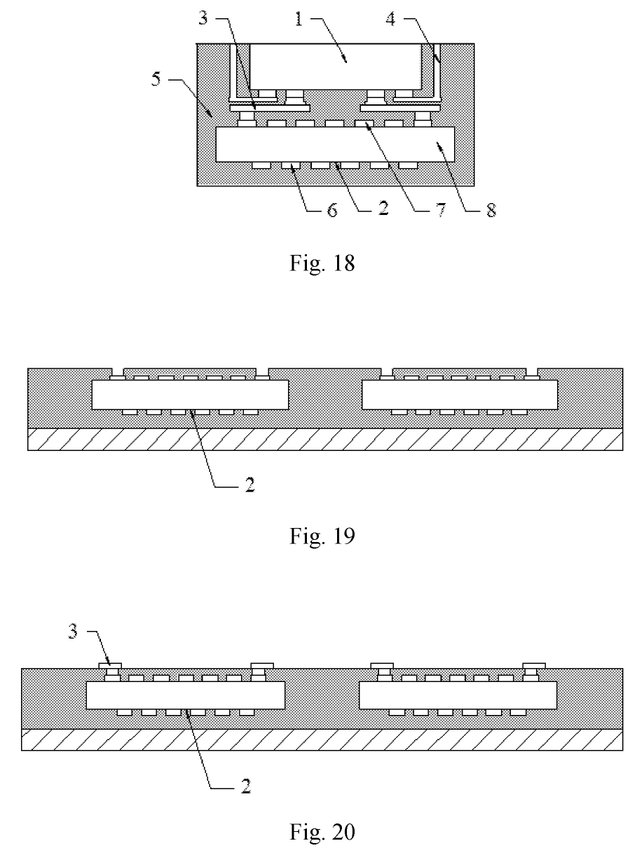

A flip-chip mounted or face-up mounted die 1 having an active surface and a back surface opposite to the active surface. When the die 1 is face-up mounted, the inductor 2 is stacked below the back surface of the die 1 (as shown in FIG. 30). When the die 1 is flip-chip mounted, the inductor 2 is stacked below the active surface of the die 1. At this time, the back surface of the die 1 is exposed outside the insulating dielectric layer 5 (as shown in FIG. 18).

An inductor 2 vertically stacked and electrically connected with the die 1 through the redistribution layer 3. The inductor 2 has a spiral structure, multi-turn overlapping structure, or segmented winding structure. The inductor 2 is formed by a layer-by-layer encapsulation and electroplating process. An inductance value range of the inductor 2 is 1 nH to 100 μH. The inductor 2 comprises a magnetic core 8. A spiral coil surrounding a surface of the magnetic core 8 is formed by etching and electroplating processes. The spiral coil comprises a line A 6, a line B, and a line C 7. The magnetic core 8 and the spiral coil are encapsulated by the insulating dielectric layer 5.

An extraction structure for electrically leading out the die 1 to an outside of the packaging structure. The extraction structure comprises metal pillars 4 and a wiring layer. The metal pillars 4 are formed by etching the insulating dielectric layer 5 to form grooves and then electroplating metal to fill the grooves. The wiring layer electrically connects the die 1 with the metal pillars 4.

Wherein, a stacking direction of the inductor 2 and the die 1 is parallel to the thickness direction of the die 1. The two, the redistribution layer 3, and the extraction structure are physically isolated by the insulating dielectric layer 5. The insulating dielectric layer 5 is a molding compound.

The structure is further integrated into a fan-out wafer-level package or a system-in-package module, or other suitable packaging modules.

The present disclosure forms spiral type or other types of inductors 2 by layer-by-layer encapsulation and electroplating, which can increase a number of coil turns in limited packaging space, increase inductance, reduce a volume of the inductor 2, miniaturize devices, and is suitable for high-integration die 1 packaging. The layer-by-layer encapsulated dielectric material effectively reduces inter-layer capacitance and increases a self-resonant frequency of the inductor 2. Electrical ports of the inductor 2 are re-laid out through the redistribution layer 3 to match positions and sizes of electrical ports of the die 1, reasonably configuring packaging space. When the inductor 2 and the die 1 are flip-chip mounted and stacked, an connection path between the die 1 and the inductor 2 is short, reducing parasitic inductance and resistance, with stable signal transmission and small electromagnetic interference, suitable for high-frequency circuit requirements. When the inductor 2 and the die 1 are face-up mounted and stacked, heat generation conduction from the inductor 2 to the die 1 is reduced. The process is mature with low cost, suitable for low-power circuit requirements. The inductor 2 and the die 1 are vertically three-dimensionally stacked, saving space with high design flexibility. A close layout of the inductor 2 and the die 1 can reduce loop impedance, reduce parasitic inductance and resistance, etc., with stable signal transmission.

It will be understood that the present disclosure has been described by way of some embodiments. Those skilled in the art will appreciate that various changes or equivalent substitutions can be made to these features and embodiments without departing from the spirit and scope of the present disclosure. In addition, under the teaching of the present disclosure, these features and embodiments can be modified to adapt to specific situations and materials without departing from the spirit and scope of the present disclosure. Therefore, the present disclosure is not limited to the specific embodiments disclosed herein. All embodiments falling within the scope of the claims of the present disclosure belong to the scope protected by the present disclosure.

What is claimed is:

1. A three-dimensional integrated packaging structure, comprising:
a die mounted in a flip-chip manner or a face-up manner, having an active surface and a back surface opposite to the active surface;
an inductor vertically stacked and electrically connected with the die through a redistribution layer;
an external connection structure for electrically leading out the die to an exterior of a packaging structure;
wherein a stacking direction of the inductor and the die is parallel to a thickness direction of the die, and the inductor, the die, the redistribution layer, and the external connection structure are physically isolated through an insulating dielectric layer.

2. The three-dimensional integrated packaging structure according to claim 1, wherein the inductor has a spiral structure, multi-turn overlapping structure, or segmented winding structure.

3. The three-dimensional integrated packaging structure according to claim 2, wherein the inductor is formed by a layer-by-layer encapsulation and electroplating process, and an inductance value of the inductor ranges from 1 nH to 100 μH.

4. The three-dimensional integrated packaging structure according to claim 3, wherein the inductor comprises a magnetic core, and a spiral coil surrounding a surface of the magnetic core is formed through etching and electroplating processes, the spiral coil comprises a trace A, a trace B, and a trace C, and the magnetic core and the spiral coil are encapsulated by the insulating dielectric layer.

5. The three-dimensional integrated packaging structure according to claim 1, wherein in a case where the die is mounted in the face-up manner, the inductor is stacked below the back surface of the die; and in a case where the die is mounted in the flip-chip manner, the inductor is stacked below the active surface of the die.

6. The three-dimensional integrated packaging structure according to claim 5, wherein in a case where the die is mounted in the face-up manner, the back surface of the die is exposed to an exterior of the insulating dielectric layer.

7. The three-dimensional integrated packaging structure according to claim 1, wherein the external connection structure comprises a metal pillar and a wiring layer, the metal pillar is formed by etching the insulating dielectric layer to form a groove and electroplating metal to fill the groove, and the wiring layer electrically connects the die with the metal pillar.

8. The three-dimensional integrated packaging structure according to claim 1, wherein a material of the insulating dielectric layer is a molding compound.

9. The three-dimensional integrated packaging structure according to claim 1, wherein the packaging structure is further integrated into a fan-out wafer-level package module or a system-in-package module.

10. A packaging method for a three-dimensional integrated structure, comprising steps of:
encapsulating an inductor: forming the inductor through a layer-by-layer encapsulation and electroplating process;
electroplating a redistribution layer: electrically redistributing the inductor after electroplating the redistribution layer;
mounting a die: mounting the die in a face-up manner or a flip-chip manner, vertically stacking and electrically connecting the die with the inductor through the redistribution layer;
electroplating an external connection structure: electrically leading out the die to an exterior of a packaging structure;
wherein a stacking direction of the inductor and the die is parallel to a thickness direction of the die, and the inductor, the die, the redistribution layer, and the external connection structure are physically isolated through an insulating dielectric layer.

11. The packaging method for a three-dimensional integrated structure according to claim 10, wherein in the step of encapsulating the inductor, the inductor has a spiral structure, multi-turn overlapping structure, or segmented winding structure.

12. The packaging method for a three-dimensional integrated structure according to claim 11, wherein in the step of encapsulating the inductor, an inductance value of the inductor ranges from 1 nH to 100 μH.

13. The packaging method for a three-dimensional integrated structure according to claim 12, wherein in the step of encapsulating the inductor, traces A are electroplated on the insulating dielectric layer, the insulating dielectric layer is used to encapsulate the traces A and is ground to expose top surfaces of the traces A, a magnetic core is mounted on the top surfaces of the traces A, the magnetic core is further encapsulated and a top surface of the magnetic core is exposed, the insulating dielectric layer is etched to expose ends of the traces A, traces B are electroplated in etched grooves respectively to connect with the traces A, traces C are electroplated on an exposed top surface of the magnetic core to connect with the traces B, the traces A, the traces B, and the traces C form a spiral coil surrounding the magnetic core, and encapsulation is performed again so that the magnetic core and the spiral coil are encapsulated by the insulating dielectric layer.

14. The packaging method for a three-dimensional integrated structure according to claim 10, wherein in the step of mounting the die, in a case where the die is mounted in the face-up manner, the inductor is stacked below the back surface of the die; and in a case where the die is mounted in the flip-chip manner, the inductor is stacked below the active surface of the die.

15. The packaging method for a three-dimensional integrated structure according to claim 14, wherein in the step of mounting the die, in a case where the die is mounted in the face-up manner, the back surface of the die is exposed to an exterior of the insulating dielectric layer.

16. The packaging method for a three-dimensional integrated structure according to claim 10, wherein in the step of electroplating the external connection structure, the external connection structure comprises a metal pillar and a wiring layer, the metal pillar is formed by etching the insulating dielectric layer to form a groove and electroplating metal to fill the groove, and the wiring layer electrically connects the die with the metal pillar.

17. The packaging method for a three-dimensional integrated structure according to claim 10, wherein a material of the insulating dielectric layer of the steps is a molding compound.

18. The packaging method for a three-dimensional integrated structure according to claim 10, wherein the packaging method further comprises integrating the packaging structure into a fan-out wafer-level package module or a system-in-package module.
